(19) United States
(12) Patent Application Publication
(10) Pub. No.: US 2008/0122032 A1
(43) Pub. Date: May 29, 2008

(54) Semiconductor devices with MIM-type decoupling capacitors and fabrication method thereof

(75) Inventors: Kuo-Chi Tu, Hsinchu (TW); Chun-Yao Chen, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: Taiwan Semiconductor Manufacturing Co., Ltd.

(21) Appl. No.: 11/504,693

(22) Filed: Aug. 16, 2006

(51) Int. Cl. H01L 29/00; H01L 21/02

(52) U.S. Cl. 257/532; 438/396; 257/E29.001; 257/E21.011

(57) ABSTRACT

A semiconductor device. The semiconductor device includes a substrate having an array region and a decoupling region, a first dielectric layer overlying the substrate, a second dielectric layer overlying the first dielectric layer, a plurality of active components formed in the first dielectric layer within the array region, a first capacitor formed in the second dielectric layer within the array region, a second capacitor formed in the second dielectric layer within the decoupling region, and a first plug formed in the first dielectric layer within the array region electrically connecting the active component and the first capacitor. The invention also provides a method of fabricating the semiconductor device.

### BACKGROUND OF THE INVENTION

1. Field of the Invention

The invention relates to a semiconductor device, and in particular to a semiconductor device with a metal-insulator-metal (MIM) type decoupling capacitor and a fabrication method thereof.

2. Description of the Related Art

Power supply lines in a semiconductor integrated circuit chip supply current to charge and discharge active and passive devices in the integrated circuit. For example, digital complementary metal-oxide-semiconductor (CMOS) circuits draw current when the clock makes a transition. During operation of circuits, the power supply lines supply transient current with a relatively high intensity, resulting in voltage noise thereon. The voltage on the power supply lines fluctuates when the fluctuation time of the transient current is short or when its parasitic inductance or parasitic resistance is large. In state-of-the-art circuits, the operational frequency of the integrated circuit is on the order of several hundreds of megahertz (MHz) to several gigahertz (GHz). In such circuits, the rising time of clock signals is very short, resulting in large voltage fluctuations in the supply lines. Undesired voltage fluctuations in power supply lines powering a circuit cause noise in internal signals and degrade noise margins. The degradation of noise margins reduces circuit reliability and can even cause circuit malfunction.

To reduce the magnitude of voltage fluctuations in the power supply lines, filtering or decoupling capacitors are usually used between the terminals of different power supply lines or between terminals of power supply lines and the ground line. Decoupling capacitors act as charge reservoirs that additionally supply current to circuits when required to prevent momentary drops in supplied voltage.

Referring to FIG. 1, a conventional semiconductor device with a MOS type decoupling capacitor is disclosed. The semiconductor device 1 comprises a substrate 2 having an array region 3 and a decoupling region 4, a plurality of transistors 5 formed on the substrate 2 within the array region 3, a first dielectric layer 6 overlying the array region 3 and the decoupling region 4, a second dielectric layer 10 overlying the first dielectric layer 6, and a capacitor 11 formed in the second dielectric layer 10 within the array region 3.

A MOS type decoupling capacitor 7 is formed in the first dielectric layer 6 within the decoupling region 4, located near the substrate 2. The structure of the decoupling capacitor 7 is similar to the transistor 5 comprising a poly gate 8 and a salicide layer 9 deposited thereon.

MOS type capacitors suffer from capacitance variations caused by the doping characteristics of the polysilicon capacitor electrode plates, and as such, these devices exhibit fairly large changes in the capacitance as a function of applied voltage. Hence, these devices have a large voltage coefficient of capacitance. In addition, the parasitic effect occurs in MOS type transistors where the capacitor is located near the substrate.

Metal-insulator-metal (MIM) type capacitors may be advantageously fabricated in upper interconnect layers of a semiconductor device wafer to mitigate such parasitic effects. MIM capacitors are also desirable, because the electrode plates are fabricated from conductive metal materials, thereby avoiding the polysilicon doping issue and polysilicon depletion associated with polysilicon-insulator-polysilicon (PIP) capacitors.

Referring to FIG. 2, a conventional semiconductor device with a back-end of line (BEOL) MIM type decoupling capacitor is disclosed. The semiconductor device 1 comprises a substrate 2 having an array region 3 and a decoupling region 4, a plurality of transistors 5 formed on the substrate 2 within the array region 3, a first dielectric layer 6 overlying the array region 3 and the decoupling region 4, a second dielectric layer 10 overlying the first dielectric layer 6, a capacitor 11 formed in the second dielectric layer 10 within the array region 3, a third dielectric layer 12 overlying the second dielectric layer 10, and a metal layer 14 formed over the third dielectric layer 12. The BEOL begins from the metal layer fabrication.

A MIM type decoupling capacitor 16 is formed above the third dielectric layer 12 within the decoupling region 4. The decoupling capacitor 16 comprises a bottom electrode 18, a top electrode 22, and a dielectric layer 20 sandwiched therebetween. The MIM decoupling capacitor fabrication is integrated with the BEOL.

Fabrication of a conventional BEOL MIM type decoupling capacitor requires additional masks and processes. Moreover, integration of the high-k dielectric layer sandwiched between the metal electrodes is difficult due to the high-temperature processes of the BEOL. Additionally, the MIM type decoupling capacitor possesses lower capacitance and occupies a larger area, reducing the margin of downward scalability.

### BRIEF SUMMARY OF THE INVENTION

The invention provides a semiconductor device comprising a substrate having an array region and a decoupling region, a first dielectric layer overlying the substrate, a second dielectric layer overlying the first dielectric layer, a plurality of active components formed in the first dielectric layer within the array region, a first capacitor formed in the second dielectric layer within the array region, a second capacitor formed in the second dielectric layer within the decoupling region, and a first plug formed in the first dielectric layer within the array region electrically connecting the active component and the first capacitor.

The invention also provides a method of fabricating a semiconductor device, comprising the following steps. A substrate having an array region and a decoupling region is provided. An active component is formed on the substrate within the array region. A first dielectric layer is deposited overlying the substrate and the active component. A first plug is formed in the first dielectric layer within the array region connecting the active component. A second dielectric layer is deposited over the first dielectric layer. A first capacitor is formed in the second dielectric layer within the array region and a second capacitor is formed in the second dielectric layer within the decoupling region, simultaneously, wherein the first capacitor connects the first plug.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 shows a cross section of a conventional semiconductor device.

FIG. 2 shows a cross section of a conventional semiconductor device.

FIGS. 3A˜3G show cross sections of a method of fabricating a semiconductor device of the invention.

FIGS. 4A˜4G show cross sections of a method of fabricating a semiconductor device of the invention.

FIGS. 5A˜5G show cross sections of a method of fabricating a semiconductor device of the invention.

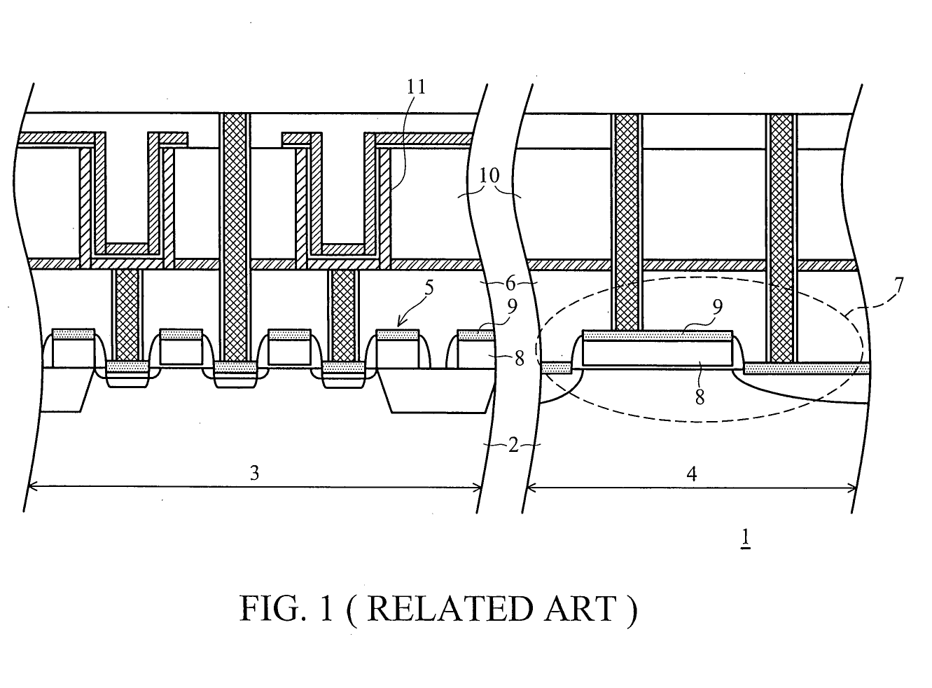

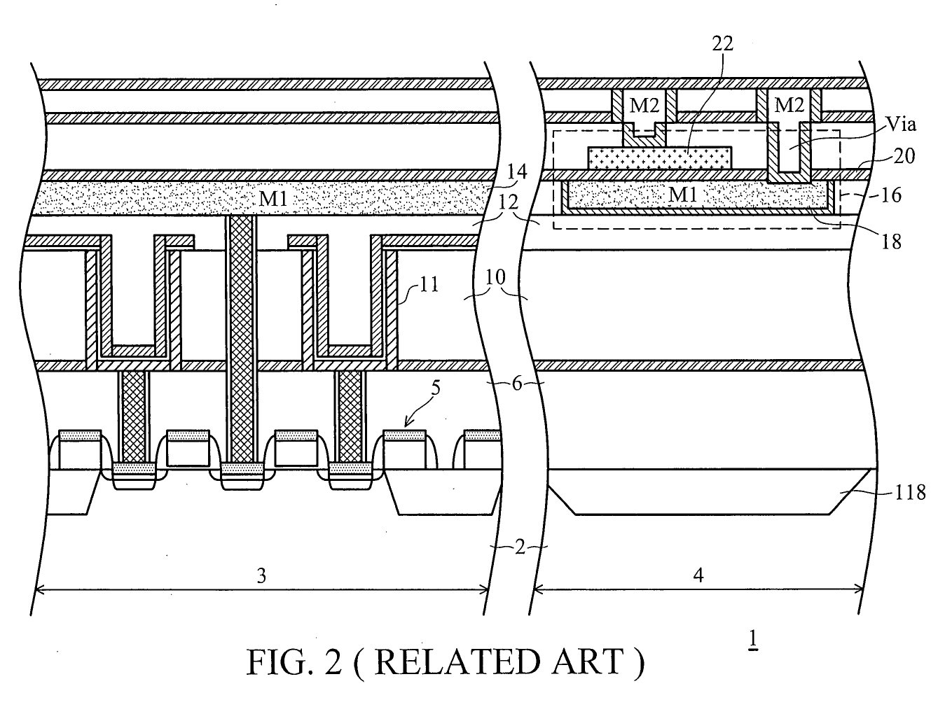

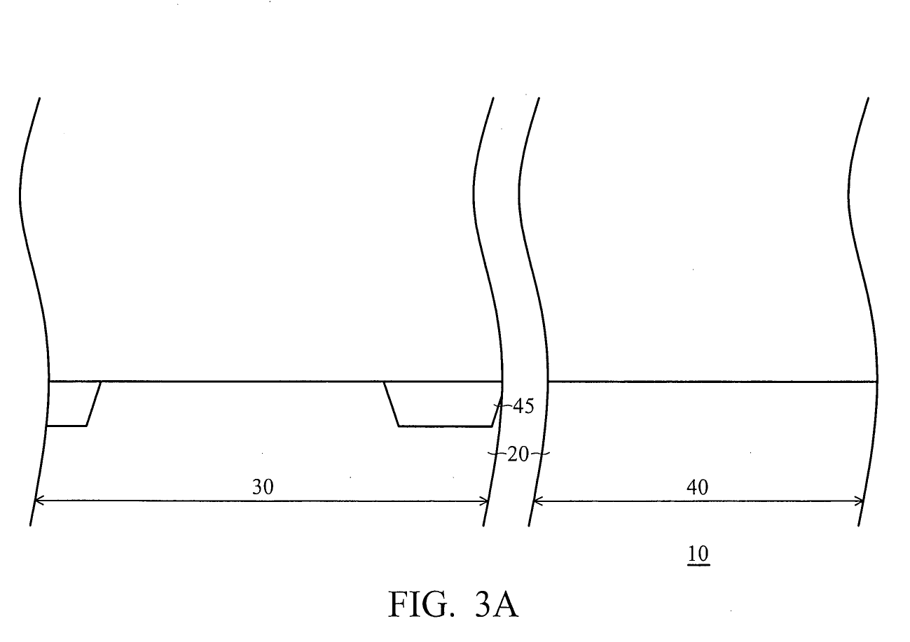

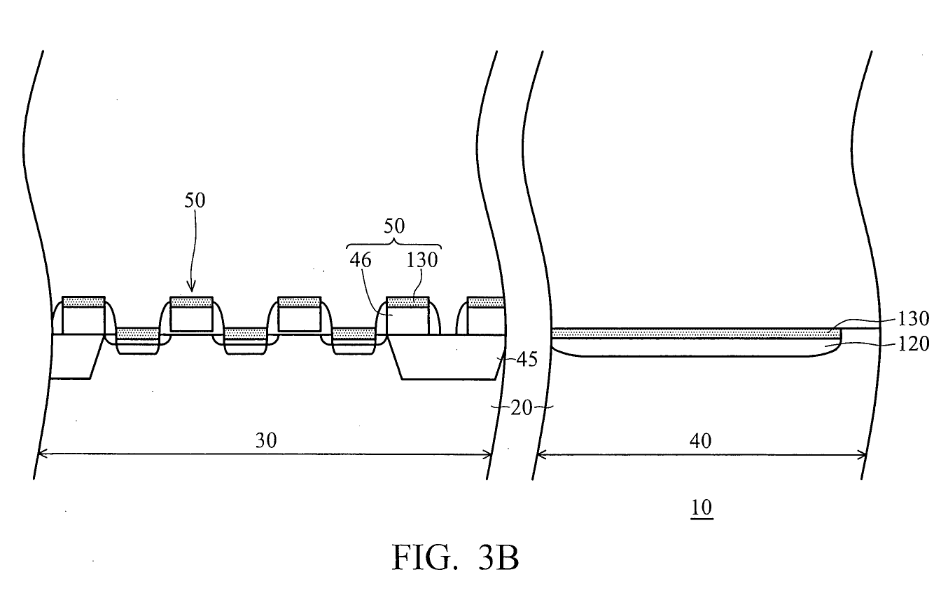

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The invention provides a semiconductor device comprising a substrate having an array region and a decoupling region, a first dielectric layer overlying the substrate, a second dielectric layer overlying the first dielectric layer, a plurality of active components formed in the first dielectric layer within the array region, a first capacitor formed in the second dielectric layer within the array region, a second capacitor formed in the second dielectric layer within the decoupling region, and a first plug formed in the first dielectric layer within the array region electrically connecting the active component and the first capacitor.

The substrate may comprise silicon, germanium, silicon germanium, semiconductor compounds, or other known semiconductor materials. The active components may be transistors or diodes. The first and second dielectric layers may comprise any known low-k materials such as silicon oxide, silicon nitride, spin-on-glass (SOG), tetraethoxysilane (TEOS), hydrogenated silicon oxide, phosphorous silicon glass (PSG), boron phosphorous silicon glass (BPSG), fluorinated silicon glass (FSG), or similar, with dielectric constant less than 4.

The first and second capacitors may be vertical metal-insulator-metal (MIM) capacitors having a first metal layer served as a bottom electrode, a second metal layer served as a top electrode, and a dielectric film sandwiched therebetween or polysilicon-insulator-polysilicon (PIP) capacitors having a first polysilicon layer served as a bottom electrode, a second polysilicon layer served as a top electrode, and a dielectric film sandwiched therebetween. Functionally, the second capacitor serves as a decoupling capacitor. The first and second metal layers may comprise Al, Au, Ag, Pd, Ta, Ti, W, or an alloy thereof. The dielectric film may comprise any known high-k materials such as aluminum oxide (Al₂O₃), hafnium oxide (HfO₂), silicon carbide (SiC), silicon nitride, tantalum oxide (Ta₂O₅), tantalum oxynitride, titanium oxide, zirconium oxide, lead zirconate titanate (PZT), strontium bismuth tantalite (SBT), bismuth strontium tantalite (BST), strontium tantalite (ST), or similar.

In the semiconductor device structure, the substrate and the second capacitor may be connected with a second plug formed in the first dielectric layer within the decoupling region. The first and second plugs may comprise Cu, Al, or W. To avoid diffusion of plug compositions into the first dielectric layer, the first and second plugs may be separated from the first dielectric layer by a barrier layer such as tantalum layer, tantalum nitride layer, titanium layer, or titanium nitride layer.

Additionally, an etch stop layer formed between the first and second dielectric layers may comprise silicon nitride or silicon oxynitride.

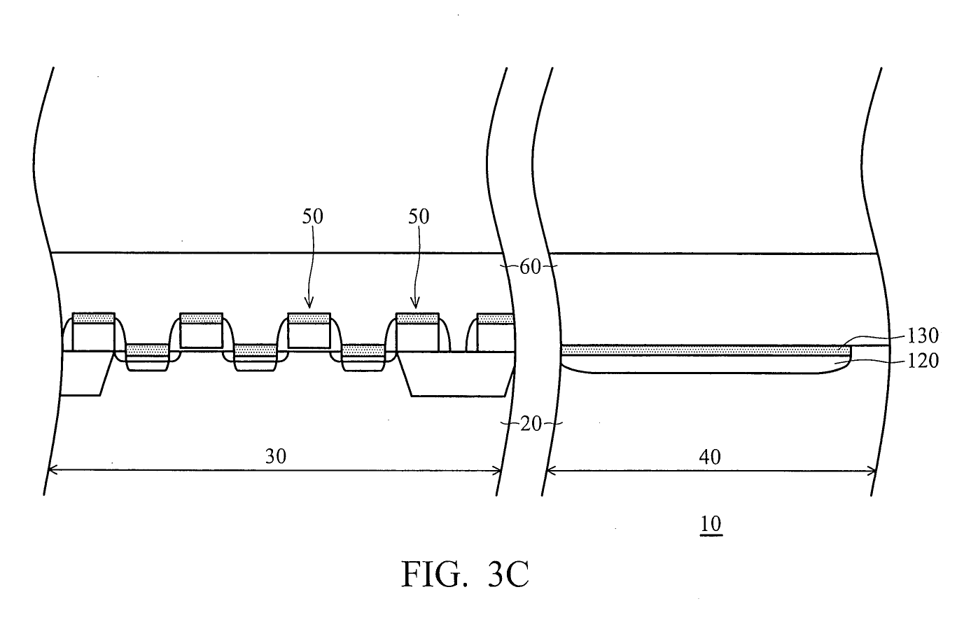

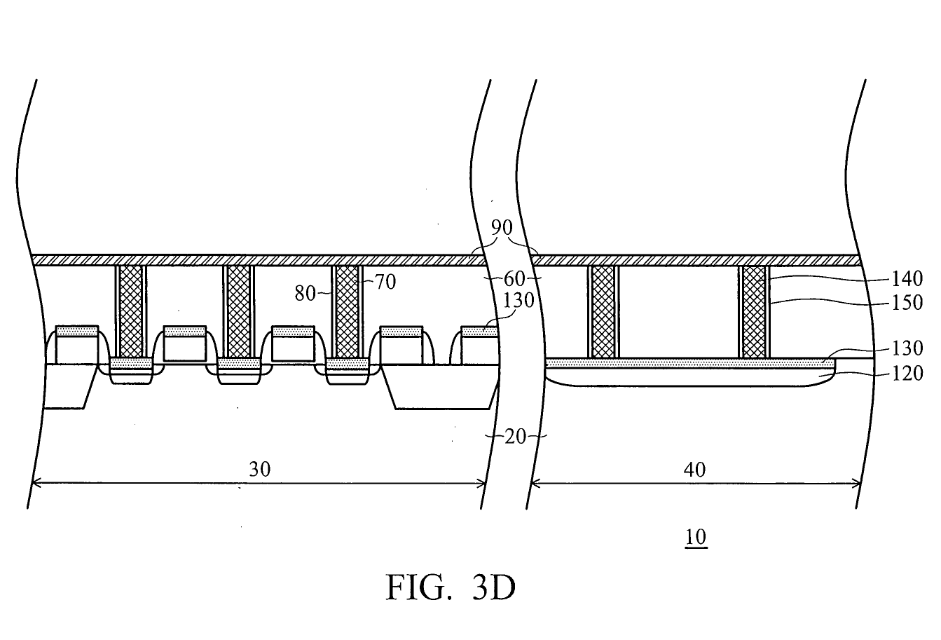

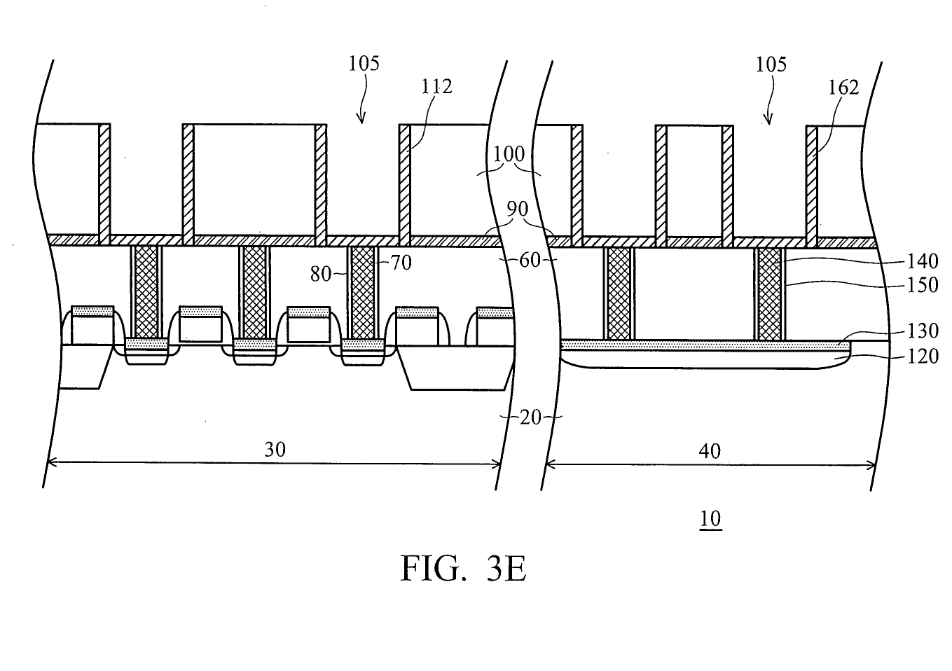

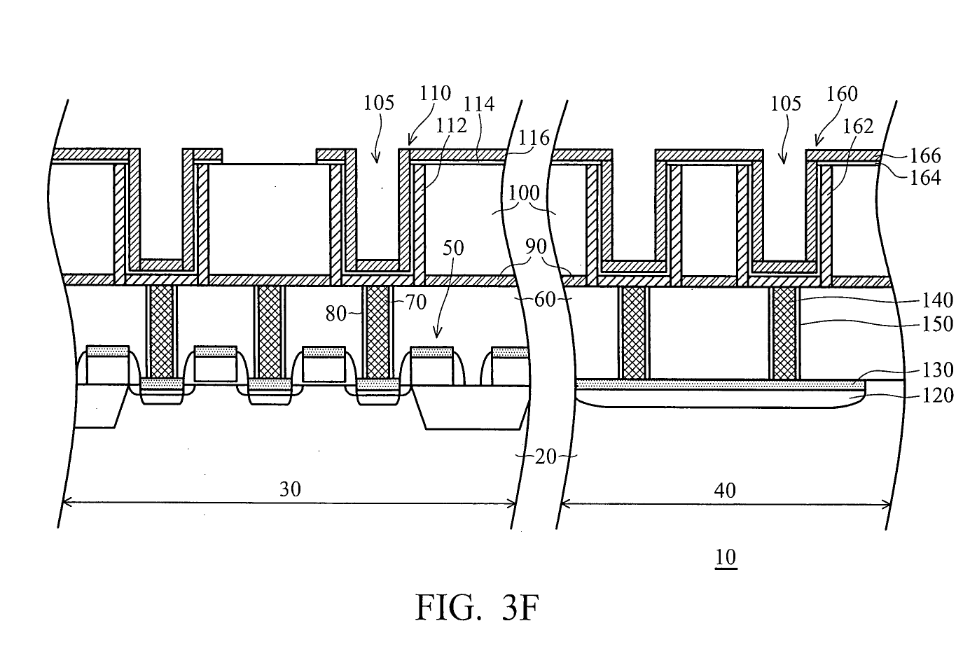

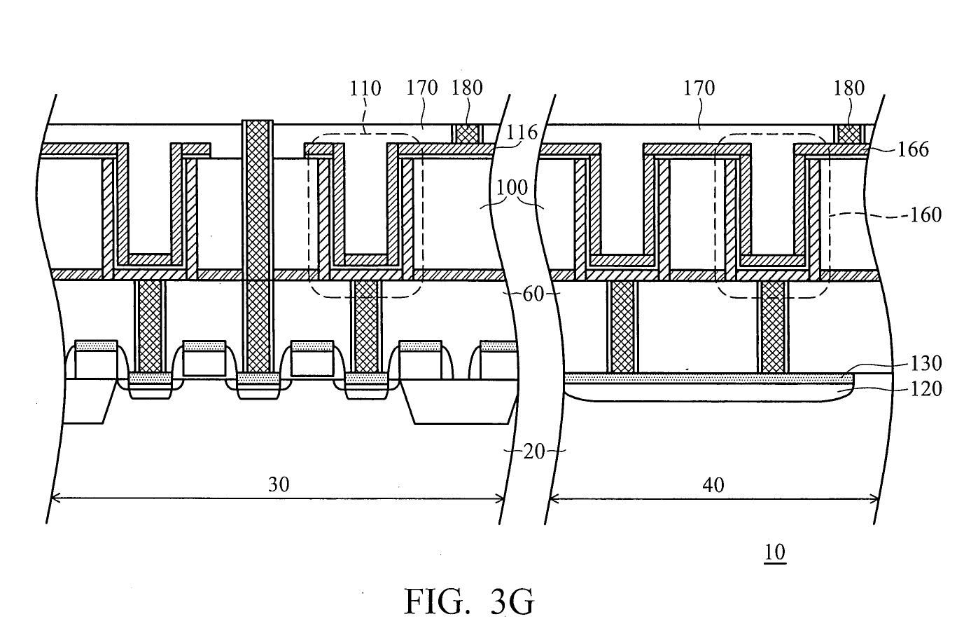

A semiconductor device structure of the invention is disclosed in FIG. 3F. The semiconductor device 10 comprises a substrate 20 having an array region 30 and a decoupling region 40, a first dielectric layer 60 overlying the substrate 20, a second dielectric layer 100 overlying the first dielectric layer 60, a plurality of active components 50 formed in the first dielectric layer 60 within the array region 30, a first capacitor 110 formed in the second dielectric layer 100 within the array region 30, a second capacitor 160 formed in the second dielectric layer 100 within the decoupling region 40, and a first plug 70 formed in the first dielectric layer 60 within the array region 30 electrically connecting the active component 50 and the first capacitor 110.

The first capacitor 110 comprises a first metal layer 112, a second metal layer 116, and a dielectric film 114 sandwiched therebetween. Similarly, the second capacitor 160 comprises a first metal layer 162, a second metal layer 166, and a dielectric film 164 sandwiched therebetween. The substrate 20 and the second capacitor 160 are connected with a second plug 140 formed in the first dielectric layer 60 within the decoupling region 40. The first plug 70 and the second plug 140 are separated from the first dielectric layer 60 by a barrier layer (80, 150), respectively. The substrate 20 within the decoupling region 40 is implanted to form an implanted area 120 and a salicide layer 130 is formed thereon such that the second plug 140 is connected to the salicide layer 130. Additionally, an etch stop layer 90 is formed between the first dielectric layer 60 and the second dielectric layer 100.

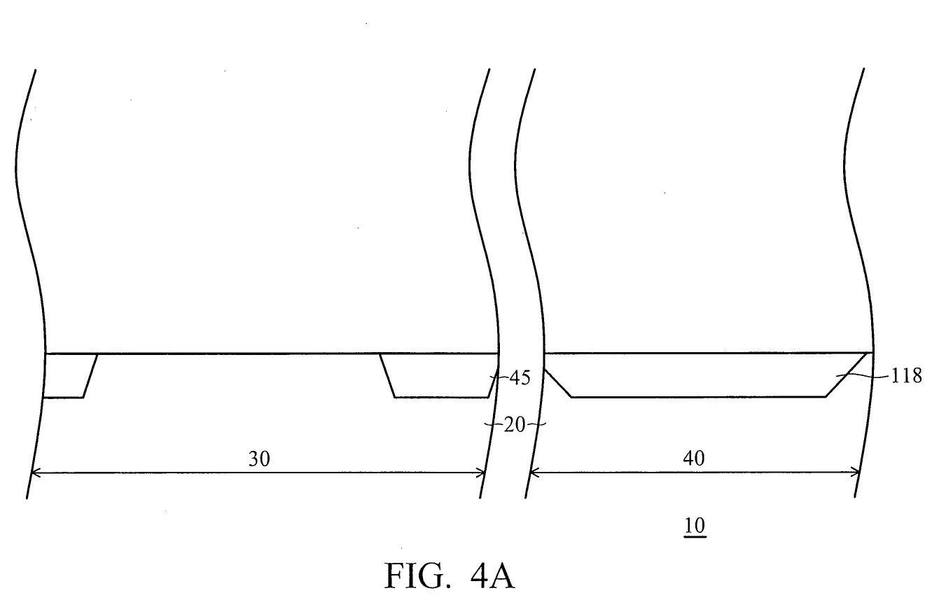

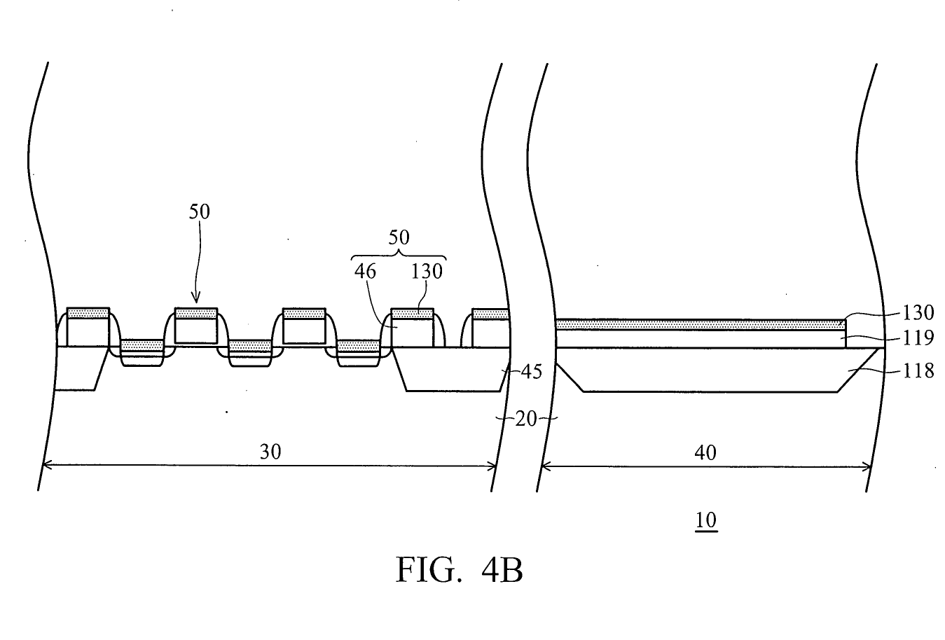

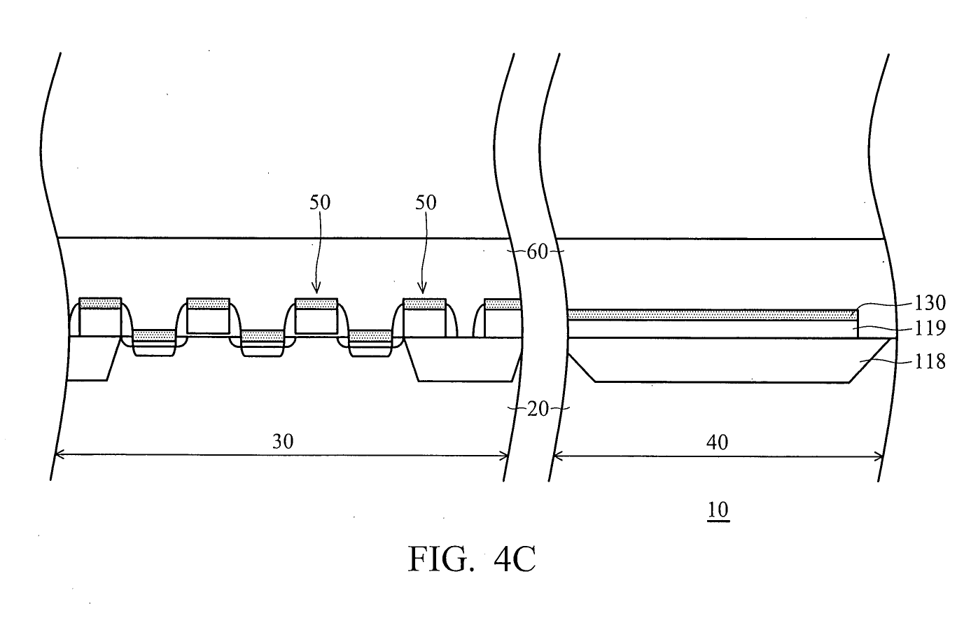

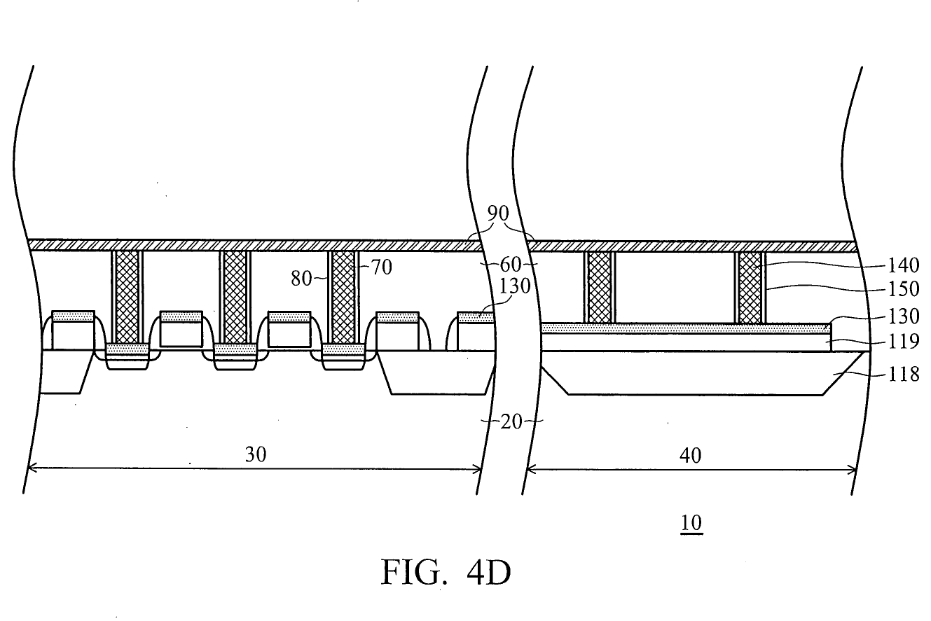

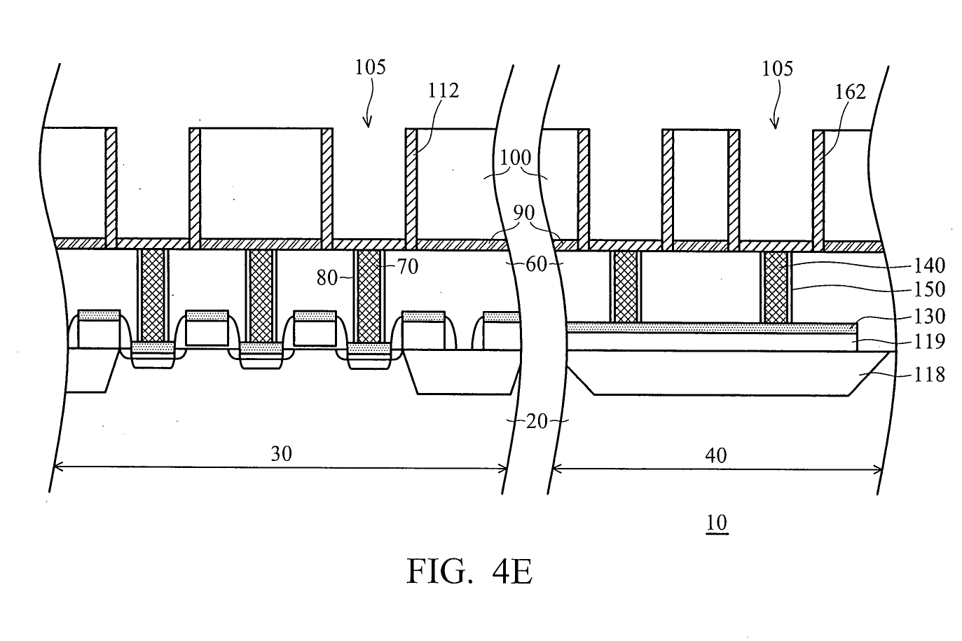

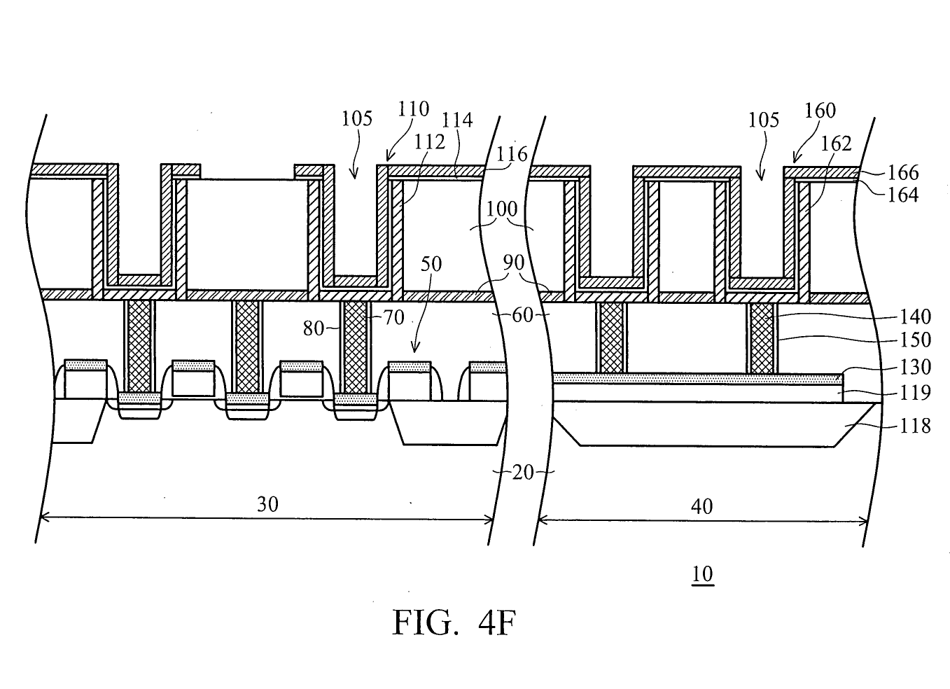

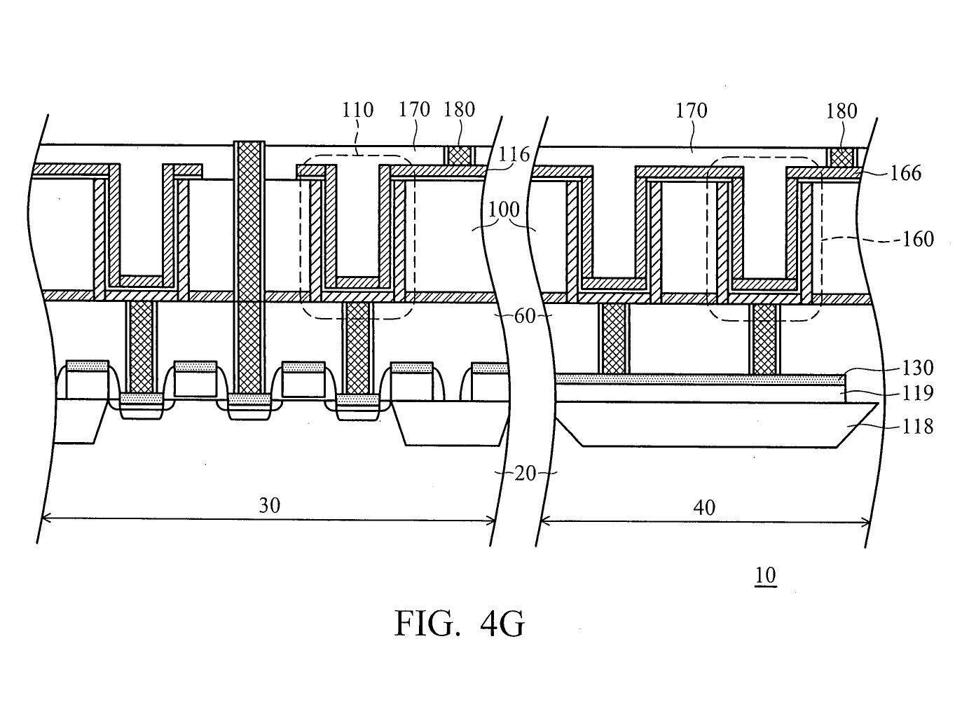

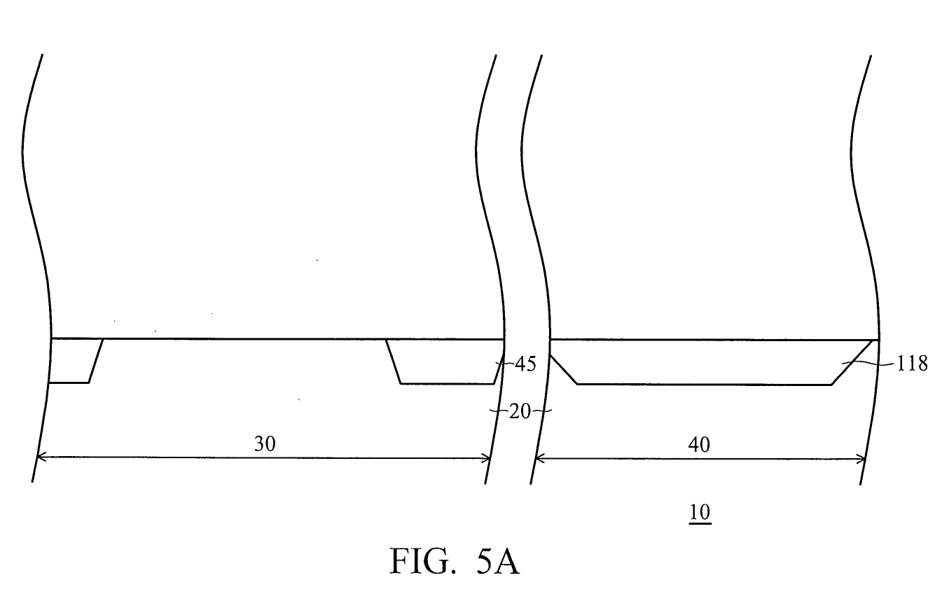

A semiconductor device structure of the invention is disclosed in FIG. 4F. The connection between the second plug 140 and the substrate 20 within the decoupling region 40 disclosed in FIG. 4F is different from FIG. 3F. The semiconductor device 10 comprises a substrate 20 having an array region 30 and a decoupling region 40, a first dielectric layer 60 overlying the substrate 20, a second dielectric layer 100 overlying the first dielectric layer 60, a plurality of active components 50 formed in the first dielectric layer 60 within the array region 30, a first capacitor 110 formed in the second dielectric layer 100 within the array region 30, a second capacitor 160 formed in the second dielectric layer 100 within the decoupling region 40, and a first plug 70 formed in the first dielectric layer 60 within the array region 30 electrically connecting the active component 50 and the first capacitor 110.

The first capacitor 110 comprises a first metal layer 112, a second metal layer 116, and a dielectric film 114 sandwiched therebetween. Similarly, the second capacitor 160 comprises a first metal layer 162, a second metal layer 166, and a dielectric film 164 sandwiched therebetween. The substrate 20 and the second capacitor 160 are connected with a second plug 140 formed in the first dielectric layer 60 within the decoupling region 40. The first plug 70 and the second plug 140 are separated from the first dielectric layer 60 by a barrier layer (80, 150), respectively. A shallow trench isolation (STI) 118 is formed in the substrate 20 within the decoupling region 40. A polysilicon layer 119 and a salicide layer 130 are formed on the substrate 20 within the decoupling region 40 such that the second plug 140 is connected to the salicide layer 130. Additionally, an etch stop layer 90 is formed between the first dielectric layer 60 and the second dielectric layer 100.

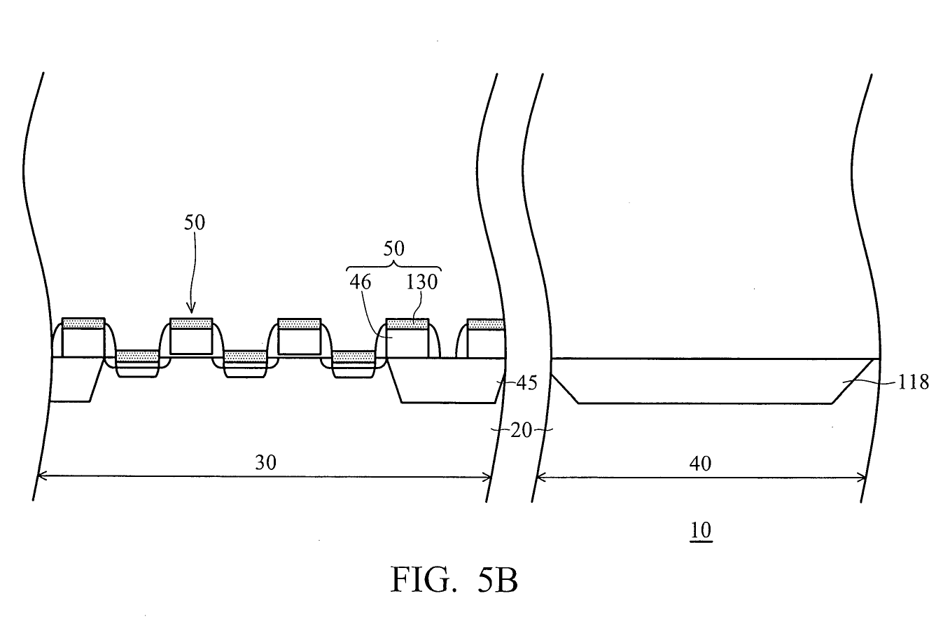

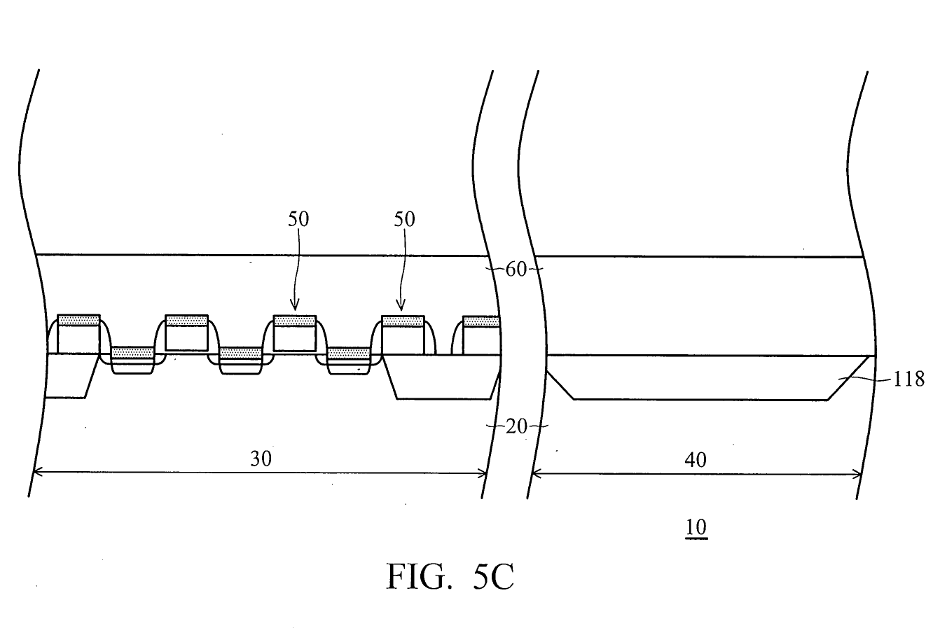

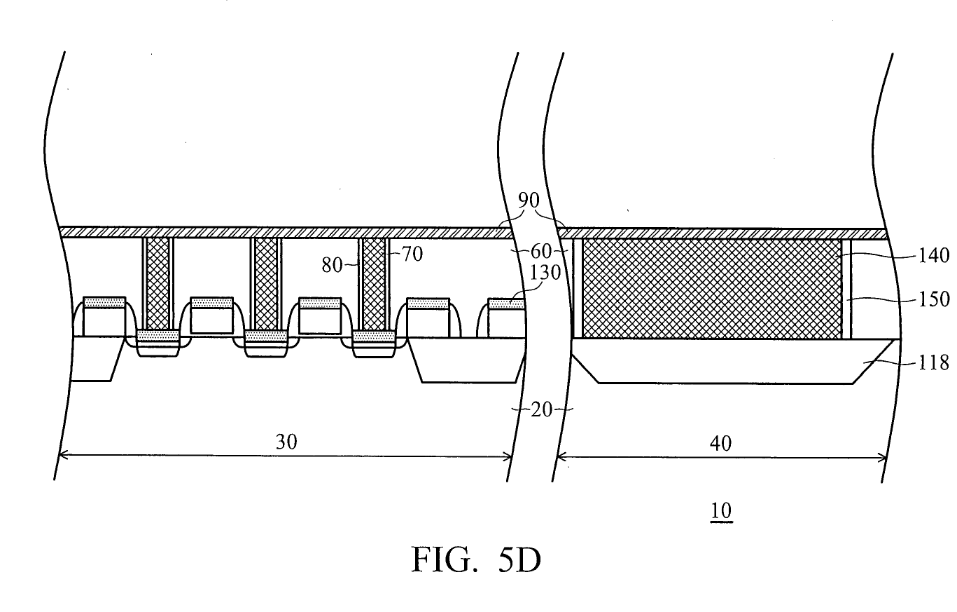

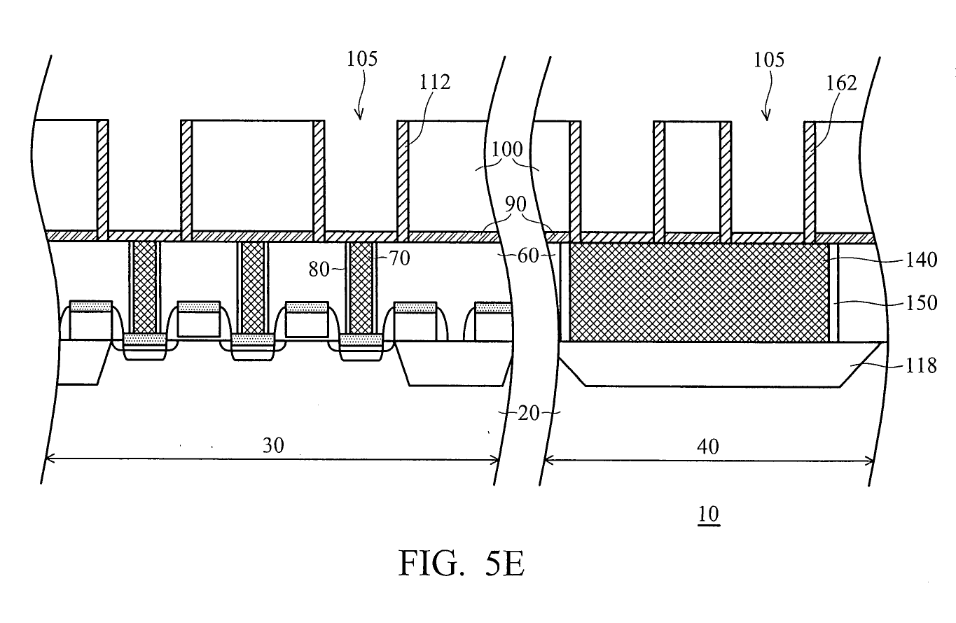

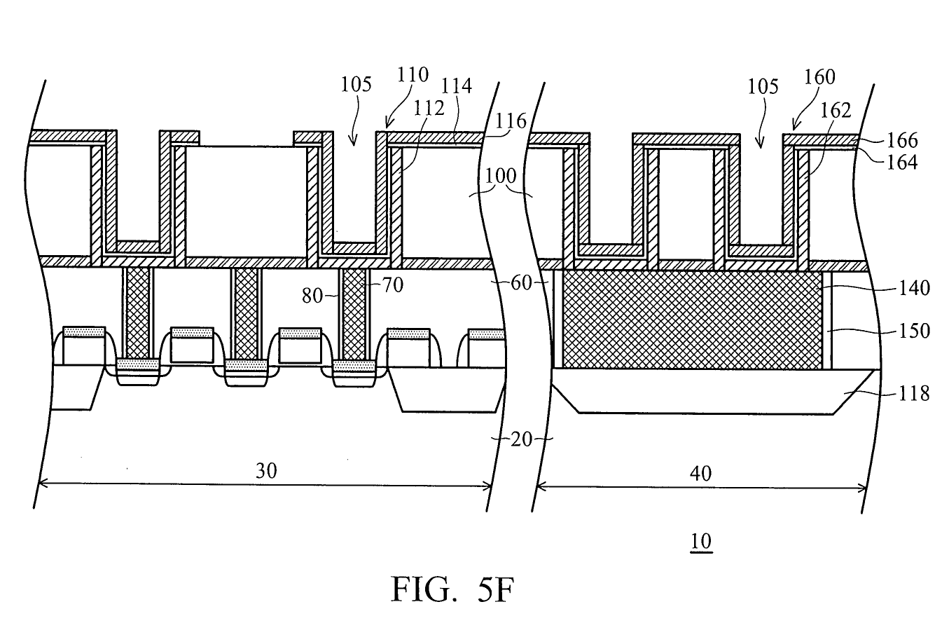

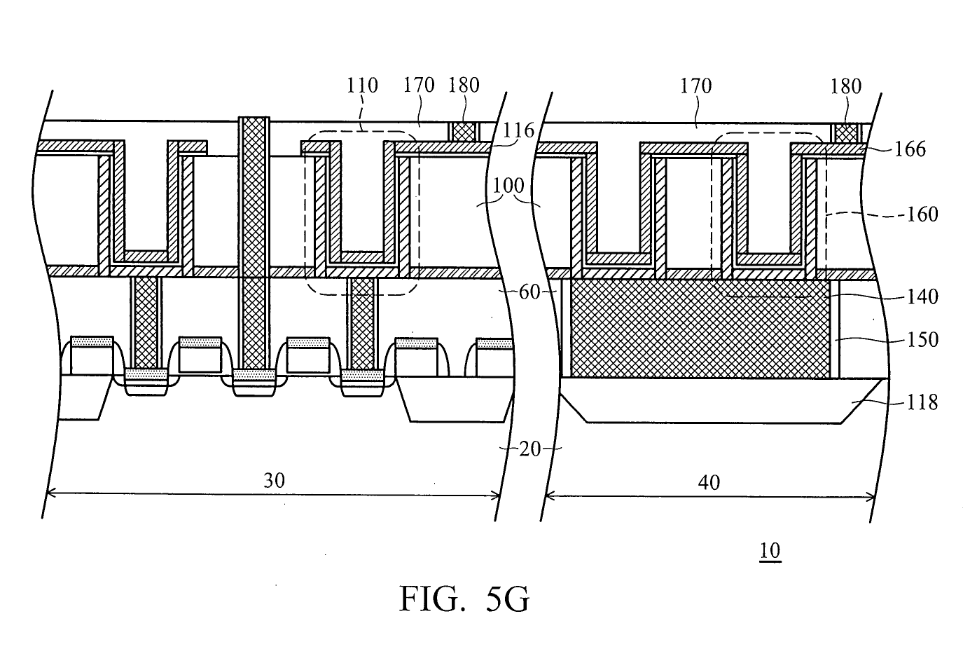

A semiconductor device structure of the invention is disclosed in FIG. 5F. The connection between the second plug 140 and the substrate 20 within the decoupling region 40 disclosed in FIG. 5F is different from FIGS. 3F and 4F. The semiconductor device 10 comprises a substrate 20 having an array region 30 and a decoupling region 40, a first dielectric layer 60 overlying the substrate 20, a second dielectric layer 100 overlying the first dielectric layer 60, a plurality of active components 50 formed in the first dielectric layer 60 within the array region 30, a first capacitor 110 formed in the second dielectric layer 100 within the array region 30, a second capacitor 160 formed in the second dielectric layer 100 within the decoupling region 40, and a first plug 70 formed in the first dielectric layer 60 within the array region 30 electrically connecting the active component 50 and the first capacitor 110.

The first capacitor 110 comprises a first metal layer 112, a second metal layer 116, and a dielectric film 114 sandwiched therebetween. Similarly, the second capacitor 160 comprises a first metal layer 162, a second metal layer 166, and a dielectric film 164 sandwiched therebetween. The substrate 20 and the second capacitor 160 are connected with a second plug 140 formed in the first dielectric layer 60 within the decoupling region 40. The first plug 70 and the second plug 140 are respectively separated from the first dielectric layer 60 by a barrier layer (80, 150). A shallow trench isolation (STI) 118 is formed in the substrate 20 within the decoupling region 40 such that the second plug 140 is connected to the shallow trench isolation (STI) 118. Additionally, an etch stop layer 90 is formed between the first dielectric layer 60 and the second dielectric layer 100.

The invention also provides a method of fabricating a semiconductor device, comprising the following steps. A substrate having an array region and a decoupling region is provided. An active components is formed on the substrate within the array region. A first dielectric layer is deposited overlying the substrate and the active component. A first plug is formed in the first dielectric layer within the array region connecting the active component. A second dielectric layer is deposited over the first dielectric layer. A first capacitor is formed in the second dielectric layer within the array region and a second capacitor is formed in the second dielectric layer within the decoupling region, simultaneously. The first capacitor connects the first plug.

The substrate may comprise silicon, germanium, silicon germanium, semiconductor compounds, or other known semiconductor materials. The active components may be transistors or diodes. The first and second dielectric layers may comprise any known low-k materials such as silicon oxide, silicon nitride, spin-on-glass (SOG), tetraethoxysilane (TEOS), hydrogened silicon oxide, phosphorous silicon glass (PSG), boron phosphorous silicon glass (BPSG), fluorinated silicon glass (FSG), or similar, with dielectric constant less than 4.

The first and second capacitors may be vertical metal-insulator-metal (MIM) capacitors having a first metal layer served as a bottom electrode, a second metal layer served as a top electrode, and a dielectric film sandwiched therebetween or polysilicon-insulator-polysilicon (PIP) capacitors having a first polysilicon layer served as a bottom electrode, a second polysilicon layer served as a top electrode, and a dielectric film sandwiched therebetween. Functionally, the second capacitor may serve as a decoupling capacitor. The first and second metal layers may comprise Al, Au, Ag, Pd, Ta, Ti, W, or an alloy thereof. The dielectric film may comprise any known high-k materials such as aluminum oxide (Al₂O₃), hafnium oxide (HfO₂), silicon carbide (SiC), silicon nitride, tantalum oxide (Ta₂O₅), tantalum oxynitride, titanium oxide, zirconium oxide, lead zirconate titanate (PZT), strontium bismuth tantalite (SBT), bismuth strontium tantalite (BST), strontium tantalite (ST), or similar.

A second plug is formed in the first dielectric layer within the decoupling region to connect the substrate and the second capacitor. The first and second plugs are formed simultaneously and may comprise Cu, Al, or W. To avoid diffusion of plug compositions into the first dielectric layer, a barrier layer, such as tantalum layer, tantalum nitride layer, titanium layer, or titanium nitride layer, is formed to separate the first and second plugs from the first dielectric layer.

Additionally, an etch stop layer is formed between the first and second dielectric layers and may comprise silicon nitride or silicon oxynitride.

The invention requires no additional masks or processes to fabricate decoupling capacitors, that is, decoupling capacitors can be easily integrated with embedded DRAM metal-insulator-metal (MIM) processes. The vertical MIM decoupling capacitor possesses a small occupied area and high capacitance. Additionally, the semiconductor structure is not limited to a MIM capacitor; it may also be a polysilicon-insulator-polysilicon (PIP) capacitor such as that used in a conventional DRAM.

A method of fabricating a semiconductor device of the invention is disclosed in FIGS. 3F˜3G. Referring to FIG. 3A, a substrate 20 having an array region 30 and a decoupling region 40 is provided. A shallow trench isolation (STI) 45 is formed therein within the array region 30.

Referring to FIG. 3B, a plurality of active components 50 comprising a poly gate 46 and a salicide layer 130 deposited thereon are formed on the substrate 20 within the array region 30 by conventional transistor fabrication methods. An implanted area 120 and a salicide layer 130 are formed simultaneously within the decoupling region 40 due to source/drain implantation and salicide deposition.

Referring to FIG. 3C, a first dielectric layer 60 is deposited overlying the substrate 20 and the active components 50 by spin-coating, electrochemical plating, chemical vapor deposition, physical vapor deposition, atomic layer deposition (ALD), molecular beam epitaxy (MBE) chemical vapor deposition, or similar.

Referring to FIG. 3D, the first dielectric layer 60 within the array region 30 and the decoupling region 40 is simultaneously etched to form vias by anisotropic etching such as sputter etching, ionic beam etching, plasma etching, or similar, exposing the salicide layer 130. Barrier layers 80 and 150 are then deposited on the sidewalls of the vias to prevent metal diffusion. Next, a conductive layer is deposited over the first dielectric layer 60 within the array region 30 and the decoupling region 40 by electrochemical plating or similar and filled into the vias. After planarization, a first plug 80 within the array region 30 and a second plug 140 within the decoupling region 40 are formed. The first plug 80 connects the active components 50. An etch stop layer 90 is then formed over the first dielectric layer 60 within the array region 30 and the decoupling region 40.

Referring to FIG. 3E, a second dielectric layer 100 is deposited over the etch stop layer 90 within the array region 30 and the decoupling region 40 by spin-coating, electrochemical plating, chemical vapor deposition, physical vapor deposition, atomic layer deposition (ALD), molecular beam epitaxy (MBE) chemical vapor deposition, or similar. The second dielectric layer 100 within the array region 30 and the decoupling region 40 is simultaneously etched to form trenches 105 by anisotropic etching such as sputter etching, ionic beam etching, plasma etching, or similar, exposing the first plug 70 and the second plug 140. Next, a first metal layer is deposited on the surface of the trenches 105 and the second dielectric layer 100. After planarization, bottom electrodes 112 and 162 within the array region 30 and the decoupling region 40, respectively, are formed.

Referring to FIG. 3F, a dielectric film 114 and 164 is deposited on the bottom electrodes 112 and 162 by chemical vapor deposition or physical vapor deposition. Next, a second metal layer is deposited on the dielectric film 114 and 164. After patterning, top electrodes 116 and 166 are formed. Thus, a first capacitor 110 comprising the bottom electrode 112, the top electrode 116, and the dielectric film 114 sandwiched therebetween is formed in the second dielectric layer 100 within the array region 30 and a second capacitor 160 comprising the bottom electrode 162, the top electrode 166, and the dielectric film 164 sandwiched therebetween is formed in the second dielectric layer 100 within the decoupling region 40, simultaneously. The first capacitor 110 connects the first plug 70. The second plug 140 connects the salicide layer 130 and the second capacitor 160.

Referring to FIG. 3G, a third dielectric layer 170 is deposited over the second dielectric layer 100 and filled into the first and second capacitors 110 and 160 within the array region 30 and the decoupling region 40 by spin-coating, electrochemical plating, chemical vapor deposition, physical vapor deposition, atomic layer deposition (ALD), molecular beam epitaxy (MBE) chemical vapor deposition, or similar. The third dielectric layer 170 within the array region 30 and the decoupling region 40 is simultaneously etched to form vias by anisotropic etching such as sputter etching, ionic beam etching, plasma etching, or similar, exposing the top electrodes 116 and 166 of the first and second capacitors 110 and 160. Next, a conductive layer is deposited over the third dielectric layer 170 within the array region 30 and the decoupling region 40 by electrochemical plating or similar and filled into the vias. After planarization, third plugs 180 within the array region 30 and the decoupling region 40 are respectively formed to contact metal lines or power supply lines.

A method of fabricating a semiconductor device of the invention is disclosed in FIGS. 4F˜4G. Referring to FIG. 4A, a substrate 20 having an array region 30 and a decoupling region 40 is provided. Shallow trench isolations (STI) 45 and 118 are formed therein within the array region 30 and the decoupling region 40, respectively.

Referring to FIG. 4B, a plurality of active components 50 comprising a poly gate 46 and a salicide layer 130 deposited thereon are formed on the substrate 20 within the array region 30 by conventional transistor fabrication methods. A polysilicon layer 119 and a salicide layer 130 are formed simultaneously within the decoupling region 40 due to poly gate and salicide deposition.

Referring to FIG. 4C, a first dielectric layer 60 is deposited overlying the substrate 20 and the active components 50 by spin-coating, electrochemical plating, chemical vapor deposition, physical vapor deposition, atomic layer deposition (ALD), molecular beam epitaxy (MBE) chemical vapor deposition, or similar.

Referring to FIG. 4D, the first dielectric layer 60 within the array region 30 and the decoupling region 40 is simultaneously etched to form vias by anisotropic etching such as sputter etching, ionic beam etching, plasma etching, or similar, exposing the salicide layer 130. Barrier layers 80 and 150 are then deposited on the sidewalls of the vias to prevent metal diffusion. Next, a conductive layer is deposited over the first dielectric layer 60 within the array region 30 and the decoupling region 40 by electrochemical plating or similar and filled into the vias. After planarization, a first plug 80 within the array region 30 and a second plug 140 within the decoupling region 40 are formed. The first plug 80 connects the active components 50. An etch stop layer 90 is then formed over the first dielectric layer 60 within the array region 30 and the decoupling region 40.

Referring to FIG. 4E, a second dielectric layer 100 is deposited over the etch stop layer 90 within the array region 30 and the decoupling region 40 by spin-coating, electrochemical plating, chemical vapor deposition, physical vapor deposition, atomic layer deposition (ALD), molecular beam epitaxy (MBE) chemical vapor deposition, or similar. The second dielectric layer 100 within the array region 30 and the decoupling region 40 is simultaneously etched to form trenches 105 by anisotropic etching such as sputter etching, ionic beam etching, plasma etching, or similar, exposing the first plug 70 and the second plug 140. Next, a first metal layer is deposited on the surface of the trenches 105 and the second dielectric layer 100. After planarization, bottom electrodes 112 and 162 within the array region 30 and the decoupling region 40, respectively, are formed.

Referring to FIG. 4F, a dielectric film 114 and 164 is deposited on the bottom electrodes 112 and 162 by chemical vapor deposition or physical vapor deposition. Next, a second metal layer is deposited on the dielectric film 114 and 164. After patterning, top electrodes 116 and 166 are formed. Thus, a first capacitor 110 comprising the bottom electrode 112, the top electrode 116, and the dielectric film 114 sandwiched therebetween is formed in the second dielectric layer 100 within the array region 30 and a second capacitor 160 comprising the bottom electrode 162, the top electrode 166, and the dielectric film 164 sandwiched therebetween is formed in the second dielectric layer 100 within the decoupling region 40, simultaneously. The first capacitor 110 connects the first plug 70. The second plug 140 connects the salicide layer 130 and the second capacitor 160.

Referring to FIG. 4G, a third dielectric layer 170 is deposited over the second dielectric layer 100 and filled into the first and second capacitors 110 and 160 within the array region 30 and the decoupling region 40 by spin-coating, electrochemical plating, chemical vapor deposition, physical vapor deposition, atomic layer deposition (ALD), molecular beam epitaxy (MBE) chemical vapor deposition, or similar. The third dielectric layer 170 within the array region 30 and the decoupling region 40 is simultaneously etched to form vias by anisotropic etching such as sputter etching, ionic beam etching, plasma etching, or similar, exposing the top electrodes 116 and 166 of the first and second capacitors 110 and 160. Next, a conductive layer is deposited over the third dielectric layer 170 within the array region 30 and the decoupling region 40 by electrochemical plating or similar and filled into the vias. After planarization, third plugs 180 within the array region 30 and the decoupling region 40 are respectively formed to contact metal lines or power supply lines.

A method of fabricating a semiconductor device of the invention is disclosed in FIGS. 5F˜5G. Referring to FIG. 5A, a substrate 20 having an array region 30 and a decoupling region 40 is provided. Shallow trench isolations (STI) 45 and 118 are formed therein within the array region 30 and the decoupling region 40, respectively.

Referring to FIG. 5B, a plurality of active components 50 comprising a poly gate 46 and a salicide layer 130 deposited thereon are formed on the substrate 20 within the array region 30 by conventional transistor fabrication methods. A polysilicon layer 119 and a salicide layer 130 are formed simultaneously within the decoupling region 40 due to poly gate and salicide deposition.

Referring to FIG. 5C, a first dielectric layer 60 is deposited overlying the substrate 20 and the active components 50 by spin-coating, electrochemical plating, chemical vapor deposition, physical vapor deposition, atomic layer deposition (ALD), molecular beam epitaxy (MBE) chemical vapor deposition, or similar.

Referring to FIG. 5D, the first dielectric layer 60 within the array region 30 and the decoupling region 40 is simultaneously etched to form vias by anisotropic etching such as sputter etching, ionic beam etching, plasma etching, or similar, exposing the salicide layer 130. Barrier layers 80 and 150 are then deposited on the sidewalls of the vias to prevent metal diffusion. Next, a conductive layer is deposited over the first dielectric layer 60 within the array region 30 and the decoupling region 40 by electrochemical plating or similar and filled into the vias. After planarization, a first plug 80 within the array region 30 and a second plug 140 within the decoupling region 40 are formed. The first plug 80 connects the active components 50. An etch stop layer 90 is then formed over the first dielectric layer 60 within the array region 30 and the decoupling region 40.

Referring to FIG. 5E, a second dielectric layer 100 is deposited over the etch stop layer 90 within the array region 30 and the decoupling region 40 by spin-coating, electrochemical plating, chemical vapor deposition, physical vapor deposition, atomic layer deposition (ALD), molecular beam epitaxy (MBE) chemical vapor deposition, or similar. The second dielectric layer 100 within the array region 30 and the decoupling region 40 is simultaneously etched to form trenches 105 by anisotropic etching such as sputter etching, ionic beam etching, plasma etching, or similar, exposing the first plug 70 and the second plug 140. Next, a first metal layer is deposited on the surface of the trenches 105 and the second dielectric layer 100. After planarization, bottom electrodes 112 and 162 within the array region 30 and the decoupling region 40, respectively, are formed.

Referring to FIG. 5F, a dielectric film 114 and 164 is deposited on the bottom electrodes 112 and 162 by chemical vapor deposition or physical vapor deposition. Next, a second metal layer is deposited on the dielectric film 114 and 164. After patterning, top electrodes 116 and 166 are formed. Thus, a first capacitor 110 comprising the bottom electrode 112, the top electrode 116, and the dielectric film 114 sandwiched therebetween is formed in the second dielectric layer 100 within the array region 30 and a second capacitor 160 comprising the bottom electrode 162, the top electrode 166, and the dielectric film 164 sandwiched therebetween is formed in the second dielectric layer 100 within the decoupling region 40, simultaneously. The first capacitor 110 connects the first plug 70. The second plug 140 connects the shallow trench isolation (STI) 118 and the second capacitor 160.

Referring to FIG. 5G, a third dielectric layer 170 is deposited over the second dielectric layer 100 and filled into the first and second capacitors 110 and 160 within the array region 30 and the decoupling region 40 by spin-coating, electrochemical plating, chemical vapor deposition, physical vapor deposition, atomic layer deposition (ALD), molecular beam epitaxy (MBE) chemical vapor deposition, or similar. The third dielectric layer 170 within the array region 30 and the decoupling region 40 is simultaneously etched to form vias by anisotropic etching such as sputter etching, ionic beam etching, plasma etching, or similar, exposing the top electrodes 116 and 166 of the first and second capacitors 110 and 160. Next, a conductive layer is deposited over the third dielectric layer 170 within the array region 30 and the decoupling region 40 by electrochemical plating or similar and filled into the vias. After planarization, third plugs 180 within the array region 30 and the decoupling region 40 are respectively formed to contact metal lines or power supply lines.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

1. A semiconductor device, comprising:
a substrate having an array region and a decoupling region;
a first dielectric layer overlying the substrate;
a second dielectric layer overlying the first dielectric layer;
a plurality of active components formed in the first dielectric layer within the array region;
a first capacitor formed in the second dielectric layer within the array region;
a second capacitor having a first metal layer, a second metal layer, and a dielectric film sandwiched therebetween formed in the second dielectric layer within the decoupling region;
a first plug formed in the first dielectric layer within the array region electrically connecting the active component and the first capacitor; and
a second plug formed in the first dielectric layer within the decoupling region connecting the substrate and the first metal layer of the second capacitor.

2. The semiconductor device as claimed in claim 1, wherein the active component is a transistor.

3. The semiconductor device as claimed in claim 1, wherein the first and second dielectric layers comprise low-k materials with dielectric constant less than 4.

4. The semiconductor device as claimed in claim 1, wherein the first capacitor is a vertical metal-insulator-metal (MIM) capacitor having a first metal layer, a second metal layer, and a dielectric film sandwiched therebetween.

5. The semiconductor device as claimed in claim 4, wherein the first and second metal layers comprise Al, Au, Ag, Pd, Ta, Ti, W, or an alloy thereof.

6. (canceled)

7. The semiconductor device as claimed in claim 1, wherein the second capacitor is a decoupling capacitor.

8. (canceled)

9. The semiconductor device as claimed in claim 1, wherein the first and second plugs comprise Cu, Al, or W.

10. A method of fabricating a semiconductor device, comprising:
providing a substrate having an array region and a decoupling region;
forming an active component on the substrate within the array region;
depositing a first dielectric layer overlying the substrate and the active component;
fonning a first plug in the first dielectric layer within the array region connecting the active component;
forming a second plug in the first dielectric layer within the decoupling region connecting the substrate;
depositing a second dielectric layer over the first dielectric layer; and
forming a first capacitor in the second dielectric layer within the array region and a second capacitor having a first metal layer, a second metal layer, and a dielectric film sandwiched therebetween in the second dielectric layer within the decoupling region, simultaneously, wherein the first capacitor connects the first plug and the first metal layer of the second capacitor connects the second plug.

11. The method of fabricating the semiconductor device as claimed in claim 10, wherein the active component is a transistor.

12. The method of fabricating the semiconductor device as claimed in claim 10, wherein the first and second dielectric layers comprise low-k materials with dielectric constant less than 4.

13. The method of fabricating the semiconductor device as claimed in claim 10, wherein the first capacitor is a vertical metal-insulator-metal (MIM) capacitor having a first metal layer, a second metal layer, and a dielectric film sandwiched therebetween.

14. The method of fabricating the semiconductor device as claimed in claim 13, wherein the first and second metal layers comprise Al, Au, Ag, Pd, Ta, Ti, W, or a alloy thereof

15. (canceled)

16. The method of fabricating the semiconductor device as claimed in claim 10, wherein the second capacitor is a decoupling capacitor.

17. (canceled)

18. The method of fabricating the semiconductor device as claimed in claim 17, wherein the first and second plugs are formed simultaneously.

19. The method of fabricating the semiconductor device as claimed in claim 17, wherein the first and second plugs comprise Cu, Al, or W.
